(19) United States
(12) Patent Application Publication
(10) Pub. No.: US 2026/0068308 A1
(43) Pub. Date: Mar. 5, 2026

(54) ANGLED GATE CONNECTOR FOR SHIFTED STACKED FET

(71) Applicant: INTERNATIONAL BUSINESS MACHINES CORPORATION, ARMONK, NY (US)

(72) Inventors: RUILONG XIE, Niskayuna, NY (US); CHEN ZHANG, Santa Clara, CA (US); SHAY REBOH, Guilderland, NY (US); JIM MAZZA, Albany, NY (US)

(21) Appl. No.: 18/826,083

(22) Filed: Sep. 5, 2024

(51) Int. Cl. H01L 27/092; H01L 27/06; H01L 29/06; H01L 29/417; H01L 29/423; H01L 29/775; H01L 29/786

(52) U.S. Cl. CPC H10D 84/856; H10D 30/43; H10D 30/6729; H10D 30/6735; H10D 30/6757; H10D 62/121; H10D 88/00

(57) ABSTRACT

A microelectronic structure that includes a stacked FET. The stacked FET includes a frontside FET and a backside FET. The frontside FET includes a frontside gate and the backside FET includes a backside gate. A bonding oxide layer separates the frontside FET and the backside FET. An angled shared gate connection located in the bonding oxide layer that connects the frontside gate to the backside gate.

### BACKGROUND

The present invention generally relates to the field of microelectronics, and more particularly to formation a shared gate contact for a stacked FET.

Nanosheet is the lead device architecture in continuing CMOS scaling. However, nanosheet technology has shown issues when scaling down such that as the devices become smaller and closer together, they are interfering with each other. With the number of devices being fitted in a smaller area it is becoming harder to form a shared gate contact between the upper and lower gates in a stacked FET.

### BRIEF SUMMARY

Additional aspects and/or advantages will be set forth in part in the description which follows and, in part, will be apparent from the description, or may be learned by practice of the invention.

A microelectronic structure that includes a stacked FET. The stacked FET includes a frontside FET and a backside FET. The frontside FET includes a frontside gate and the backside FET includes a backside gate. A bonding oxide layer separates the frontside FET and the backside FET. An angled shared gate connection located in the bonding oxide layer that connects the frontside gate to the backside gate.

A microelectronic structure that includes a stacked FET. The stacked FET includes a frontside FET and a backside FET. The frontside FET includes a frontside gate and the backside FET includes a backside gate. A bonding oxide layer separates the frontside FET and the backside FET. An angled shared gate connection located in the bonding oxide layer that connects the frontside gate to the backside gate. A frontside gate cut located adjacent to the frontside gate and the frontside gate cut contacts the backside gate. The frontside gate cut is located in a gate region and the source/drain region of the frontside FET. A bottom core source/drain contact extends through the frontside gate cut in the source/drain region to contact the backside source/drain.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a plurality of the stacked nanosheet transistors, in accordance with the embodiment of the present invention.

FIG. 2 illustrates a cross-section X of the stacked nanosheet transistor after the initial processing of the backside (bottom) FET of the stacked FET and the formation of the alternating layers for frontside (upper) FET, in accordance with the embodiment of the present invention.

FIG. 3 illustrates a cross-section Y1 of the gate region after the initial processing of the backside (bottom) FET of the stacked FET and the formation of the alternating layers for frontside (upper) FET, in accordance with the embodiment of the present invention.

FIG. 4 illustrates a cross-section Y2 of the source/drain region after the initial processing of the backside (bottom) FET of the stacked FET and the formation of the alternating layers for frontside (upper) FET, in accordance with the embodiment of the present invention.

FIG. 5 illustrates a cross-section X of the stacked nanosheet transistor after the initial processing of the frontside (upper) FET, in accordance with the embodiment of the present invention.

FIG. 6 illustrates a cross-section Y1 of the gate region after the initial processing of the frontside (upper) FET, in accordance with the embodiment of the present invention.

FIG. 7 illustrates a cross-section Y2 of the source/drain region after the initial processing of the frontside (upper) FET, in accordance with the embodiment of the present invention.

FIG. 8 illustrates a cross-section X of the stacked nanosheet transistor after removal of the dummy gate and the removal of the upper sacrificial layers, in accordance with the embodiment of the present invention.

FIG. 9 illustrates a cross-section Y1 of the gate region after removal of the dummy gate and the removal of the upper sacrificial layers, in accordance with the embodiment of the present invention.

FIG. 10 illustrates a cross-section X of the stacked nanosheet transistor after formation of an upper liner, in accordance with the embodiment of the present invention.

FIG. 11 illustrates a cross-section Y1 of the gate region after formation of an upper liner, in accordance with the embodiment of the present invention.

FIG. 12 illustrates a cross-section Y2 of the source/drain region after formation of an upper liner, in accordance with the embodiment of the present invention.

FIG. 13 illustrates a cross-section X of the stacked nanosheet transistor after formation of a sacrificial fill layer, in accordance with the embodiment of the present invention.

FIG. 14 illustrates a cross-section Y1 of the gate region after formation of a sacrificial fill layer, in accordance with the embodiment of the present invention.

FIG. 15 illustrates a cross-section Y2 of the source/drain region after formation of a sacrificial fill layer, in accordance with the embodiment of the present invention.

FIG. 16 illustrates a cross-section X of the stacked nanosheet transistor after formation and patterning a hardmask, in accordance with the embodiment of the present invention.

FIG. 17 illustrates a cross-section Y1 of the gate region after formation and patterning a hardmask, in accordance with the embodiment of the present invention.

FIG. 18 illustrates a cross-section Y2 of the source/drain region after formation and patterning a hardmask, in accordance with the embodiment of the present invention.

FIG. 19 illustrates a cross-section Y1 of the gate region after formation of the angled trenches, in accordance with the embodiment of the present invention.

FIG. 20 illustrates a cross-section X of the stacked nanosheet transistor after removal of the hardmask and removal of the sacrificial fill layer, in accordance with the embodiment of the present invention.

FIG. 21 illustrates a cross-section Y1 of the gate region after removal of the hardmask and removal of the sacrificial fill layer, in accordance with the embodiment of the present invention.

FIG. 22 illustrates a cross-section Y2 of the source/drain after removal of the hardmask and removal of the sacrificial fill layer, in accordance with the embodiment of the present invention.

FIG. 23 illustrates a cross-section X of the stacked nanosheet transistor after formation of the upper gate, in accordance with the embodiment of the present invention.

FIG. 24 illustrates a cross-section Y1 of the gate region after formation of the upper gate, in accordance with the embodiment of the present invention.

FIG. 25 illustrates a cross-section Y2 of the source/drain after formation of the upper gate, in accordance with the embodiment of the present invention.

FIG. 26 illustrates a cross-section Y1 of the gate region after formation of upper gate cuts, in accordance with the embodiment of the present invention.

FIG. 27 illustrates a cross-section Y2 of the source/drain after formation of upper gate cuts, in accordance with the embodiment of the present invention.

FIG. 28 illustrates a cross-section X of the stacked nanosheet transistor after additional frontside processing of the stacked FETs, in accordance with the embodiment of the present invention.

FIG. 29 illustrates a cross-section Y1 of the gate region after additional frontside processing of the stacked FETs, in accordance with the embodiment of the present invention.

FIG. 30 illustrates a cross-section Y2 of the source/drain after additional frontside processing of the stacked FETs, in accordance with the embodiment of the present invention.

FIG. 31 illustrates a cross-section X of the stacked nanosheet transistor after backside processing of the stacked FETs, in accordance with the embodiment of the present invention.

FIG. 32 illustrates a cross-section Y1 of the gate region after backside processing of the stacked FETs, in accordance with the embodiment of the present invention.

FIG. 33 illustrates a cross-section Y2 of the source/drain after backside processing of the stacked FETs, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment.

Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings.

These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration. ” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection. ” As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like.

Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards forming a shared gate connection between a gate of the upper (frontside) FET and a gate of the bottom (backside) FET.

The shared gate connection is usually a straight vertical connection located in the bonding oxide layer between the upper and lower FET. When forming the gate cuts, the dimensions of the shared gate connection can be impacted. The gate cut can extend downwards through a portion of the straight vertical shared gate connection, thus reducing the dimensions of the shared gate connection. The reduced dimension causes an increase in the resistance of the shared gate connection and affects the performance of the shared gate connection.

The present invention solves this problem by angling the shared gate connection. The reduction of the dimensions of the shared gate can be prevented by angling the shared gate connection, thus preventing the gate cut from reducing the dimensions of the angled shared gate.

The shared gate connection has an angle in the range of about 35 to 75 degrees, more preferably in the range of 45 to 60 degrees, when measured from the top of the bottom gate to the inclined surface of the angled shared gate connection that is located closest to the gate cut and the bottom gate.

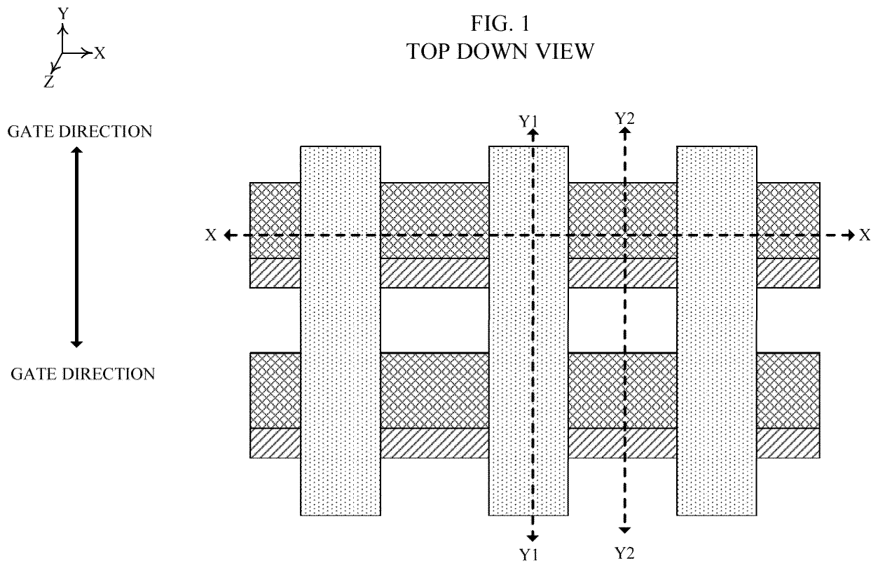

FIG. 1 illustrates a top-down view of multiple devices, in accordance with the embodiment of the present invention. The cross-section X extends horizontally through the stacked nanosheet transistors or field-effect-transistors. Cross section Y1 is perpendicular to cross section X, where cross section Y1 is through a gate region that spans across multiple adjacent stacked nanosheet transistors or field-effect-transistors. Cross section Y2 is perpendicular to cross section X, where cross section Y2 is through a source/drain region that spans across multiple adjacent nanosheet transistors or field-effect-transistors. Cross-section X is perpendicular to the gate direction and cross-section Y1 and Y2 are parallel to the gate direction.

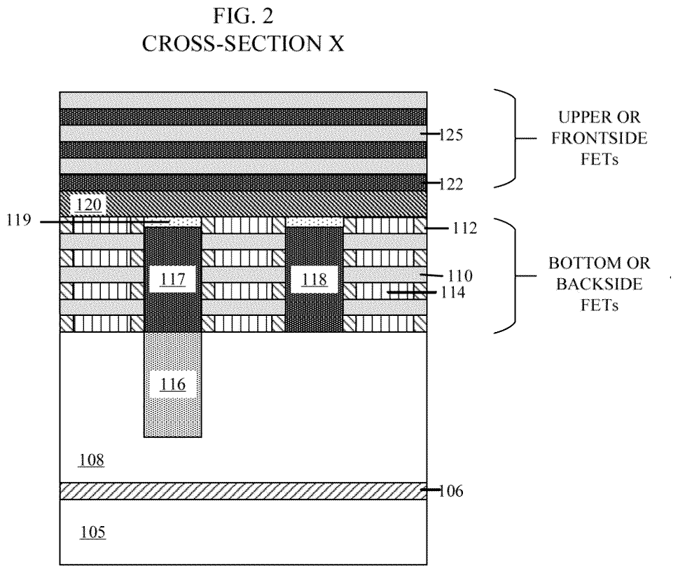

Referring now to FIGS. 2, 3 and 4, a structure is shown during an intermediate step of a method of fabricating after the initial processing of the backside (bottom) FET of the stacked FET and the formation of the alternating layers for frontside (upper) FET. FIG. 2 illustrates the staked nanosheet FET that includes the first substrate 105, the etch stop 106, the second substrate 108, the processed (i.e. formed) bottom (or backside) FETs and the initial formation of the upper (or frontside) FETs.

The first substrate 105 and the second substrate 108 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of semiconductor materials can be used as the semiconductor material of first substrate 105 and the second substrate 108. In some embodiments, first substrate 105 and the second substrate 108 includes both semiconductor materials and dielectric materials. The semiconductor first substrate 105 and the second substrate 108 may also comprise an organic semiconductor or a layered semiconductor such as, for example, Si/SiGe, a silicon-on-insulator or a SiGe-on-insulator. A portion or the entire semiconductor first substrate 105 and the second substrate 108 may also be comprised of an amorphous, polycrystalline, or monocrystalline. The semiconductor substrate 105 and the second substrate 108 may be doped, undoped or contain doped regions and undoped regions therein.

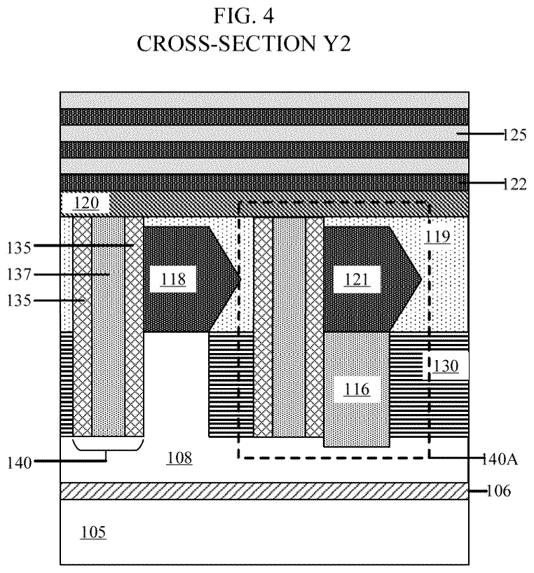

The backside or bottom FETs includes a placeholder 116, a plurality of bottom channel layers 110, a bottom gate 114, bottom inner spacer 112, bottom source/drains 117, 118, a bottom frontside interlayer dielectric layer 119. The plurality of bottom channel layers 110 can be comprised of, for example, Si. Only one placeholder 116 is illustrated in FIG. 2, but multiple placeholders 116 can be present. FIG. 4 illustrates another placeholder 116 located beneath a different source/drain 121. The bottom frontside interlayer dielectric layer 119 is located on top of the bottom source/drains 117, 118, 121.

The bottom source/drains 117, 118, 121, can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

Bottom gate 114 or backside gate 114 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W.

A bonding oxide layer 120 is located on top of the bottom or backside FETs. The bottom surface of the bonding oxide layer 120 is in contact with the bottom gate 114, the bottom inner spacer 112, and the bottom frontside interlayer dielectric layer 119.

Alternating layers are formed on top of the bonding oxide layer 120 for the initial processing of the frontside or upper FETs. The alternating layers are comprised of a plurality of upper sacrificial layers 122 and a plurality of upper channel layers 125 (or frontside channel layers). The plurality of upper channel layers 125 can be comprised of, for example, Si. The plurality of sacrificial layers 122 can be comprised of SiGe, where Ge is in the percentage of 15 to 35%. One of the sacrificial layers 122 is formed directly on top of the bonding oxide layer 120.

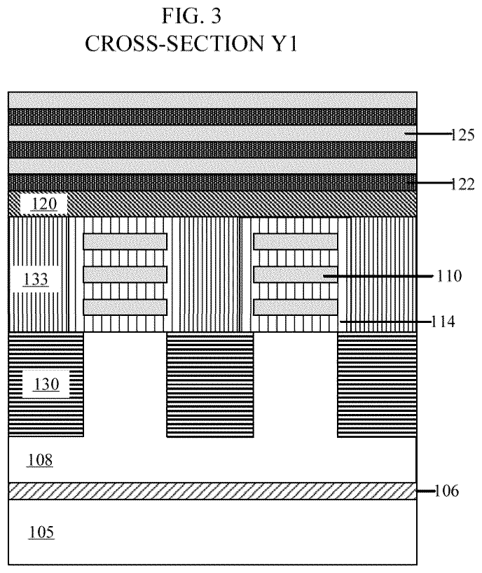

FIG. 3 illustrates the gate region after the initial processing of the backside (bottom) FET of the stacked FET and the formation of the alternating layers for frontside (upper) FET. FIG. 3 illustrates the shallow trench isolation layer 130 that was formed in the trenches made in the second substrate 108 during the processing of the bottom or backside FETs. A lower gate isolation layer 133 is located around and between adjacent bottom gates 114. The lower gate isolation layer 133 isolates the bottom gates 114 from each other. The bonding oxide layer 120 is in contact with the lower gate isolation layer 133.

FIG. 4 illustrates the source/drain region after the initial processing of the backside (bottom) FET of the stacked FET and the formation of the alternating layers for frontside (upper) FET. FIG. 4 illustrates the bottom placeholder pillars 140 that includes a pair of vertical spacer segments 135 and a placeholder pillar 137. The placeholder pillar 137 is located between the pair of vertical spacer segments 135. The bottom placeholder pillars 140 are located next to the bottom source/drains 118, 121. One of the bottom placeholder pillars 140 can be located next to placeholder 116 as emphasized by dashed box 140A, such that, placeholder 116 can be in contact with one of the vertical spacer segments 135.

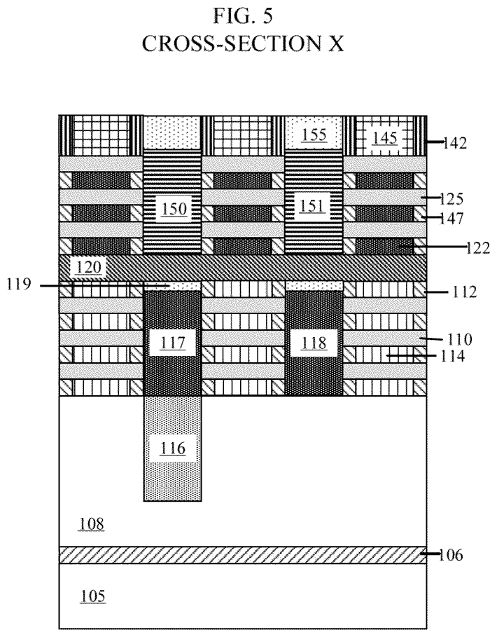

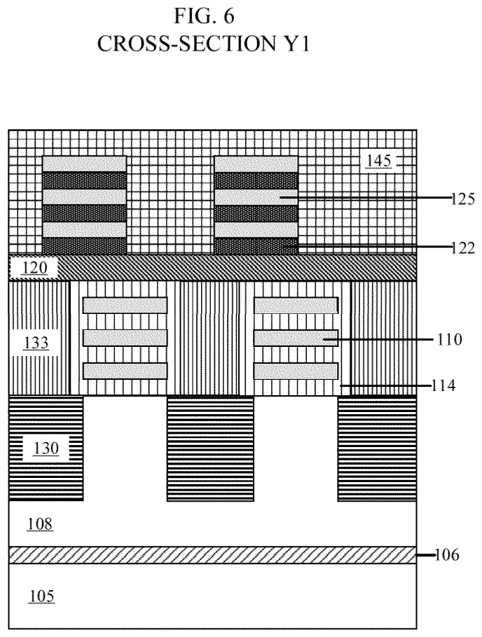

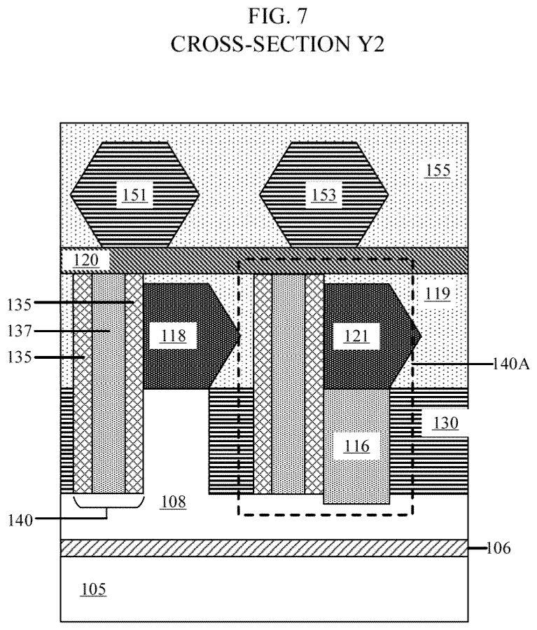

FIGS. 5, 6, and 7 illustrate the processing stage after the initial processing of the frontside (upper) FET. Dummy gate 145 is formed on top of the alternating layers and processed to form a plurality of columns of the dummy gate 145. A frontside upper gate spacer 142 is formed on top of the alternating layers and located adjacent to the columns of the dummy gate 145. The alternating layers are separated into a plurality of stacked columns. The upper sacrificial layers 122 are recessed to form empty spaces/voids (not shown) around the upper channel layers 125. These voids/empty spaces are filled with an upper inner spacer 147. Upper source/drains 150, 151, 153 are formed in the space between the stacked columns in the source/drain region. An upper frontside interlayer dielectric layer 155 is located on top of the upper source/drains 150, 151, 153. FIG. 6 illustrates how the stacked columns of the upper or frontside FETs (that include the upper sacrificial layers 122 and upper channel layers 125) are offset from the bottom channel layers 110. There is some overlap between the upper channel layers 125 and the bottom channel layers 110. FIG. 7 illustrates the source/drain region where the upper source/drains 151, 153 are offset from the bottom source/drains 118, 121.

The upper source/drains 150, 151, 153, can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

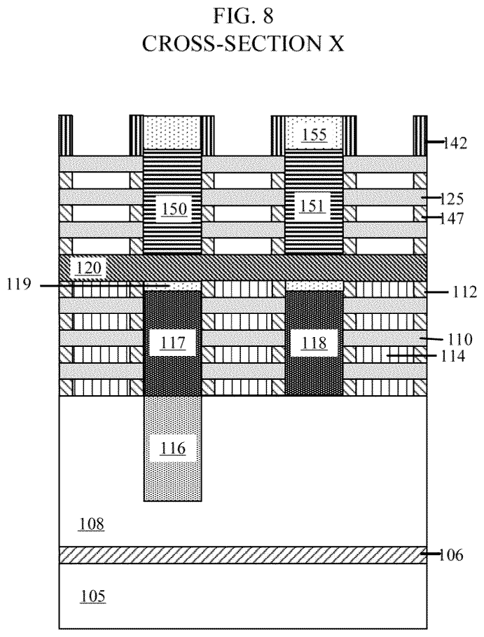

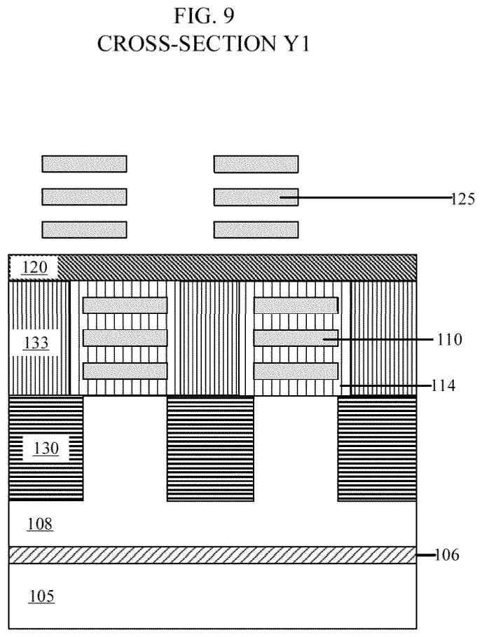

FIGS. 8 and 9 illustrate the processing stage after removal of the dummy gate 145 and the removal of the upper sacrificial layers 122. Dummy gate 145 and the upper sacrificial layers 122 are removed to expose the upper channel layers 125 of each of the plurality of stacked columns.

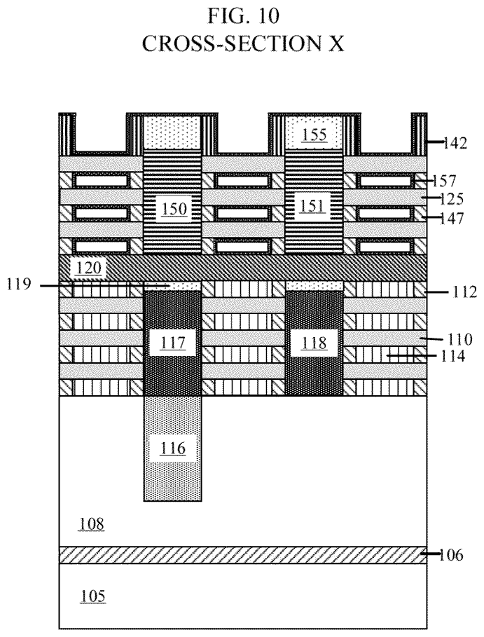

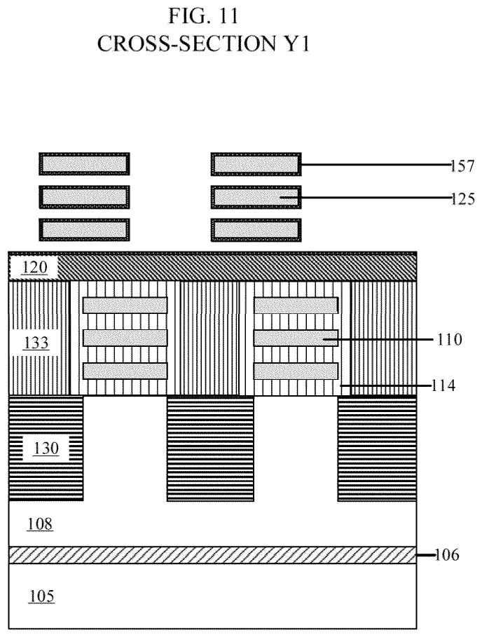

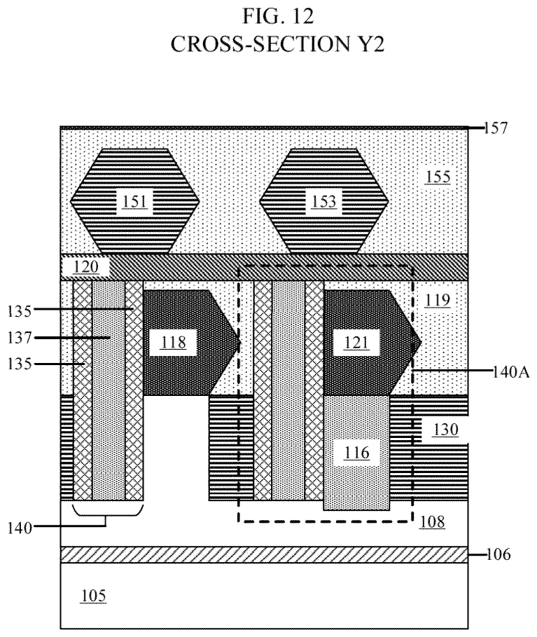

FIGS. 10, 11, 12 illustrate the processing stage after formation of an upper liner 157. An upper liner 157 is formed on the exposed surfaces of the upper or frontside stacked FETs. The upper liner 157 can be comprised of a high-k dielectric material, for example, HfO₂. The upper liner 157 is in contact with the upper channel layers 125, the upper inner spacer 147, the frontside upper gate spacer 142, and the upper frontside interlayer dielectric layer 155.

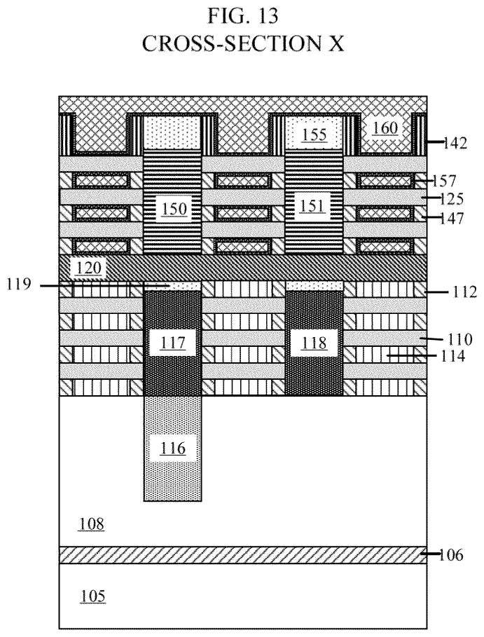

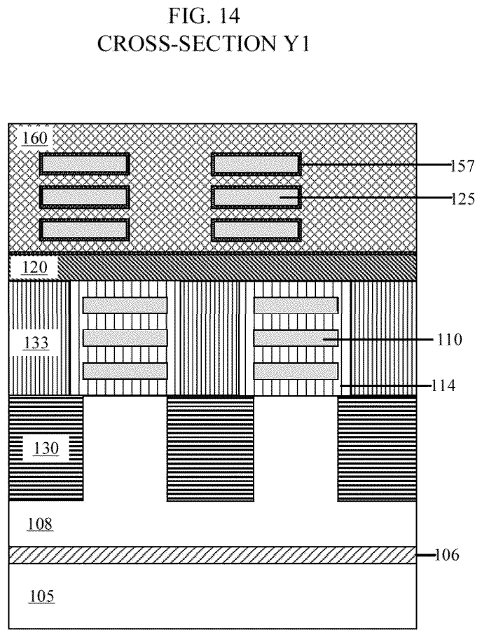

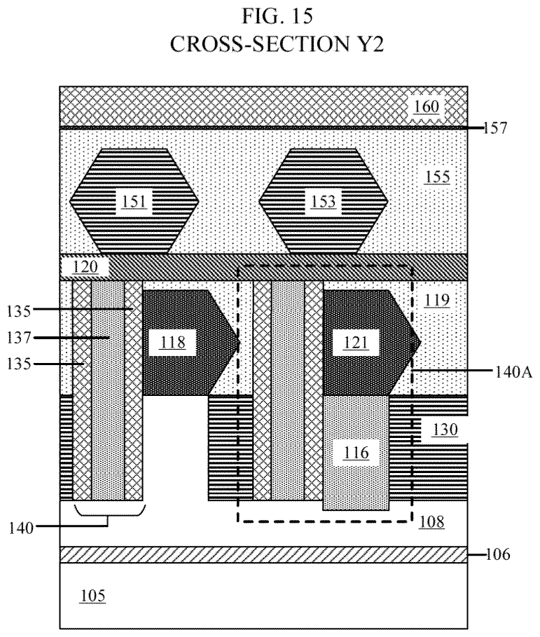

FIGS. 13, 14, 15 illustrate the processing stage after formation of a sacrificial fill layer 160. A sacrificial fill layer 160 is formed on top of the upper liner 157. The sacrificial fill layer 160 fills the space created by the removal of the dummy gate 145 and the removal of the plurality of sacrificial layers 122. The sacrificial fill layer 160 can be formed by, for example, a TiN thin layer formation and amorphous-Si fill, followed by an annealing process.

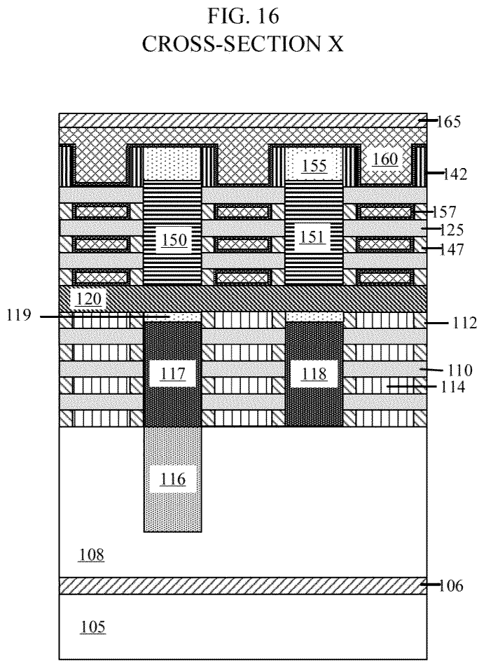

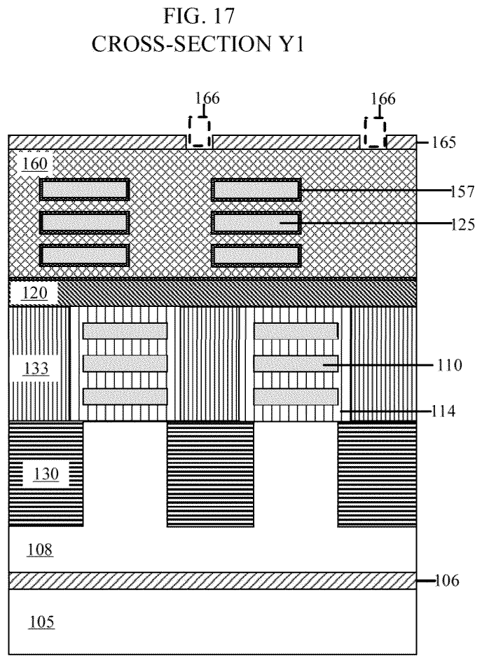

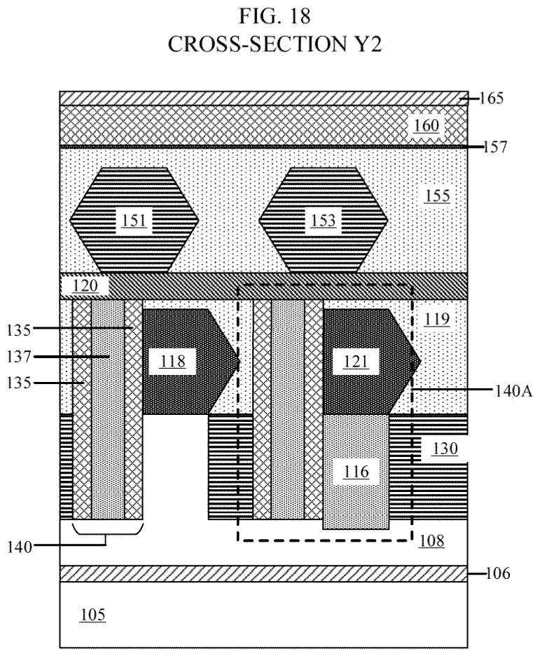

FIGS. 16, 17, and 18 illustrate the processing stage after formation and patterning a hardmask 165. Hardmask 165 is formed on top of the sacrificial fill layer 160. The hardmask 165 is patterned to form one or more openings, as emphasized by dashed box 166, which exposes portions of the sacrificial fill layer 160. The openings 166 are offset from the upper channel layers 125 and are offset from the bottom channel layers 110.

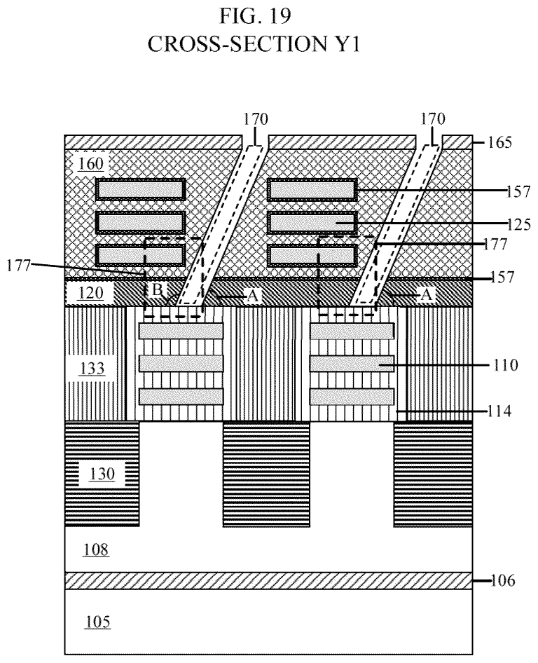

FIG. 19 illustrates the processing stage after formation of the angled trenches 170. Utilizing an angled reactive ion etch (RIE) process to form an angled trench 170 in the sacrificial fill layer 160, the upper liner 157, and the bonding oxide layer 120. The angled trench 170 exposes a portion of the top surface of the bottom gate 114. The angled trench 170 has an angle A, which is an acute angle, in a range of about 35 to 70 degrees, more preferably, in a range of about 45 to 65 degrees. Angle A is measured from the top of the bottom gate 114 to a wall of the angled trench 170, such that the measurement of angle A is an acute angle. Angle B as illustrated in FIG. 19 is an obtuse angle that is larger than angle A, but reference angle A is being used for the measurement of the angle for the angled trench 170. Angle trench 170 extends beneath the plurality of upper channel layers 127, as emphasized by dashed box 177. Since angle trench 170 extends at an angle a portion of the angle trench 170 overlaps with the plurality of upper channel layers 125, as emphasized by dashed box 177.

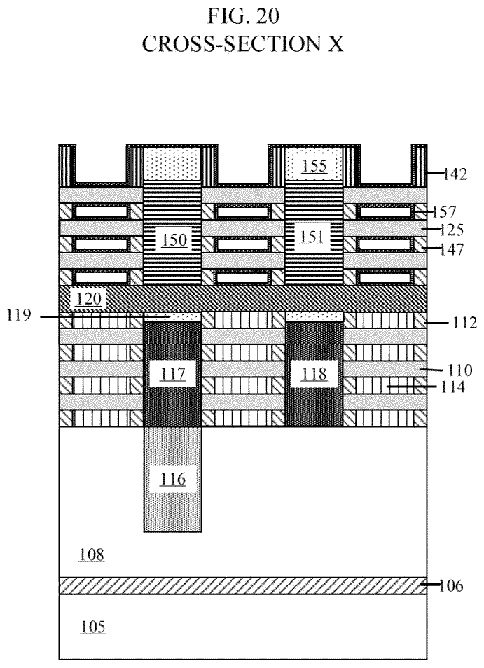

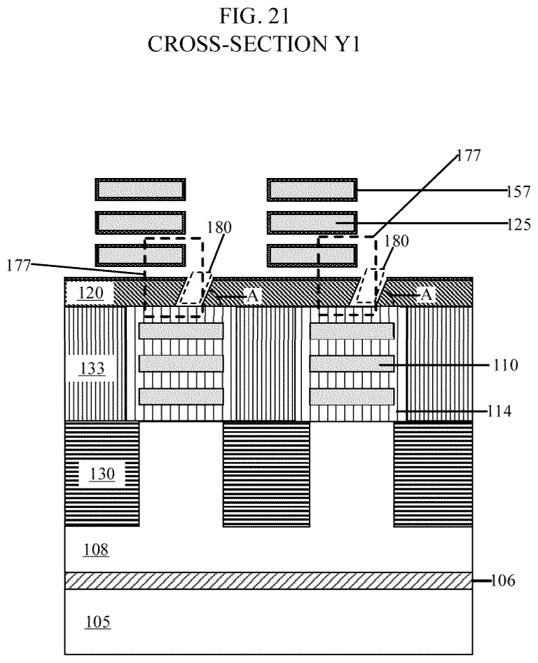

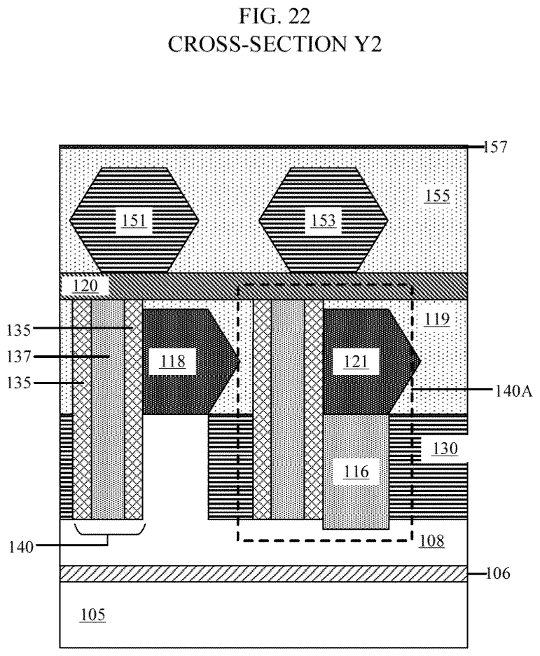

FIGS. 20, 21, and 22 illustrate the processing stage after removal of the hardmask 165 and removal of the sacrificial fill layer 160. The hardmask 165 is removed and the sacrificial fill layer 160 is removed. FIG. 21 illustrates that after the removal of these layers a portion of the angle trench 170 remains, hereinafter this portion will be referred to as the angle connecting trench 180. The angle connecting trench 180 is located in the bonding layer 120 and a portion of the upper liner 157 that is located on top of the bonding layer 120. The angle connecting trench 180 has an angle A in a range of about 35 to 70 degrees, more preferably, in a range of about 45 to 65 degrees. Angle A is measured from the top of the bottom gate 114 to a wall of the angle connecting trench 180, such that the measurement of angle A is an acute angle. The angle connecting trench 180 vertically overlaps the plurality of upper channels 125, as emphasized by dashed box 177.

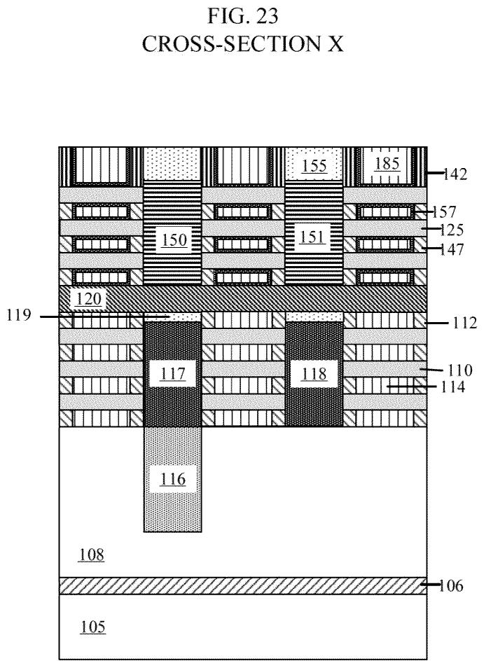

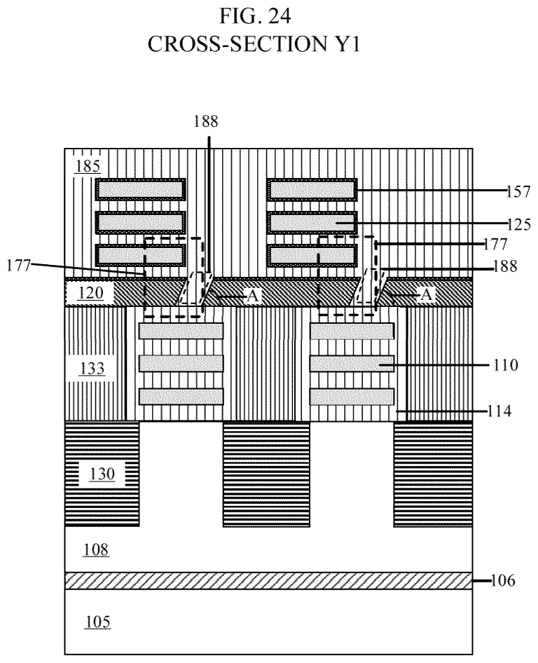

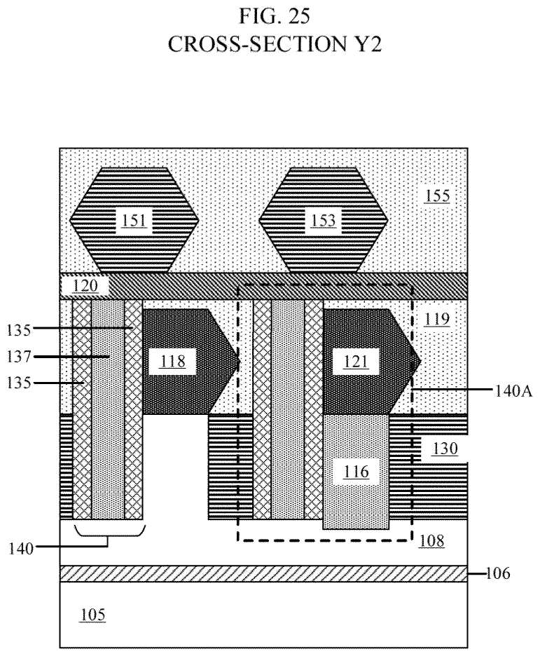

FIGS. 23, 24, and 25 illustrate the processing stage after formation of the upper gate 185. Upper gate 185 or the frontside gate 185 is formed in the empty space created by the removal of the sacrificial fill layer 160. Upper gate 185 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W. The upper gate 185 fills the angle connecting trench 180 to form the angled shared gate connection 188. Excess upper gate 185 material is removed by, for example, chemical mechanical planarization (CMP) causing the upper liner 157 located on top of the upper frontside interlayer dielectric layer 155 to be removed in the source/drain region.

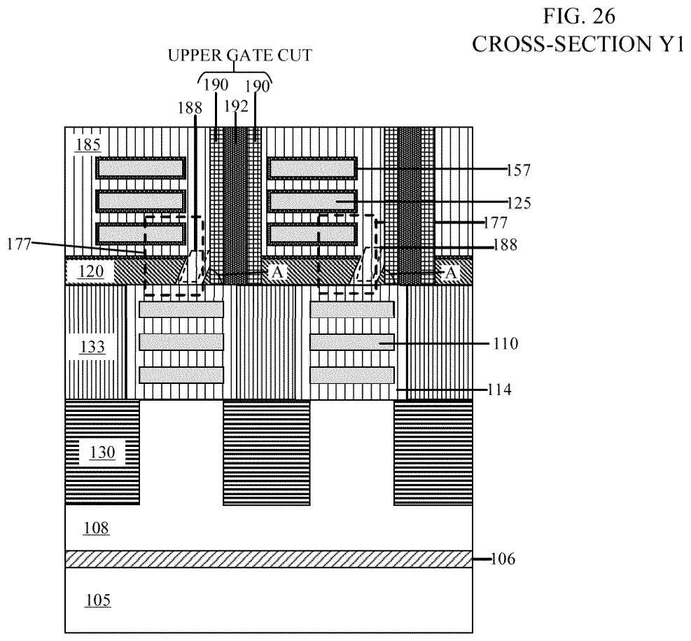

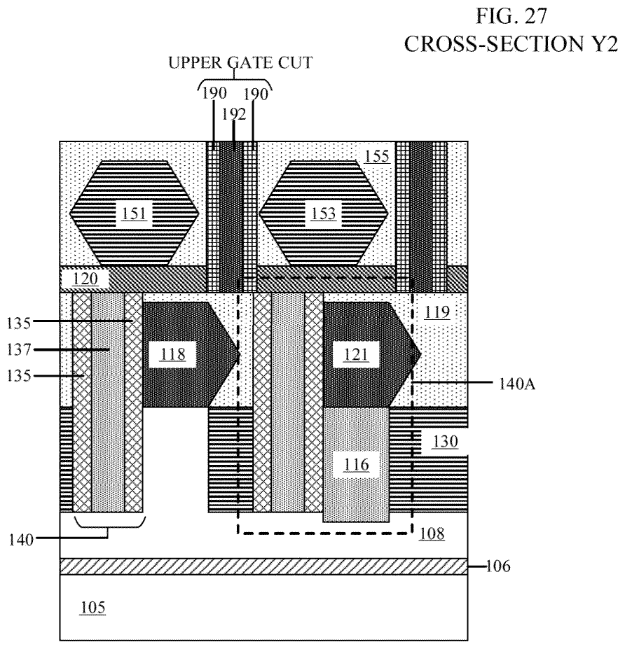

FIG. 26, and 27 illustrate the processing stage after formation of upper gate cuts. The upper gate cuts are formed in the gate region to separate the upper gate 185 into separate sections. The upper gate cut or frontside gate cut extends into the source/drain region as illustrated in FIG. 27. The upper gate cuts include at least two vertical segments 190 and a core segment 192. The core segment 192 is sandwiched between two vertical segments 190. The upper gate cut extends through the upper gate 185, through the bonding layer 120 to contact the bottom gate 114, the lower gate isolation layer 133, and the bottom frontside interlayer dielectric layer 119. The upper gate cut can contact the bottom placeholder pillars 140. The upper gate cut can contact a small portion of the angled shared gate connection 188. The upper gate cut only removes a small segment of the angled shared gate connection 188 since the angled shared gate connection 188 is angled away from the vertical segment 190. A triangle shape portion of the bonding layer 120 can still be located between the vertical segment 190 and the angled shared gate connection 188.

If the shared gate connection (i.e., a gate connection between the upper gate and lower gate) was a straight vertical passage (i.e., straight from top to bottom) and during the formation of vertical gate cuts that overlap with the shared gate connection would lead to a large portion of the shared gate connection to be removed, which would lead to an increase in the resistance of the shared gate connection. The gate cut would extend through the entire height of the share gate connection, thus reducing the lateral dimensions of the shared gate connection.

In contrast the angled shared gate connection 188 of the present invention prevents the upper gate cut from significantly reducing the lateral dimensions of the angled shared gate connection 188. This is accomplished by the angled shared gate connection 188 extending at an angle from the gate cut, to prevent the gate cut from passing through the entire vertical height of the angled shared gate connection 188. Furthermore, since the angled shared gate connection 188 and the upper channel layers 125 vertically overlap, as emphasized by dashed box 177, further prevents the gate cut from extending through the entire height of the angled shared gate connection 188.

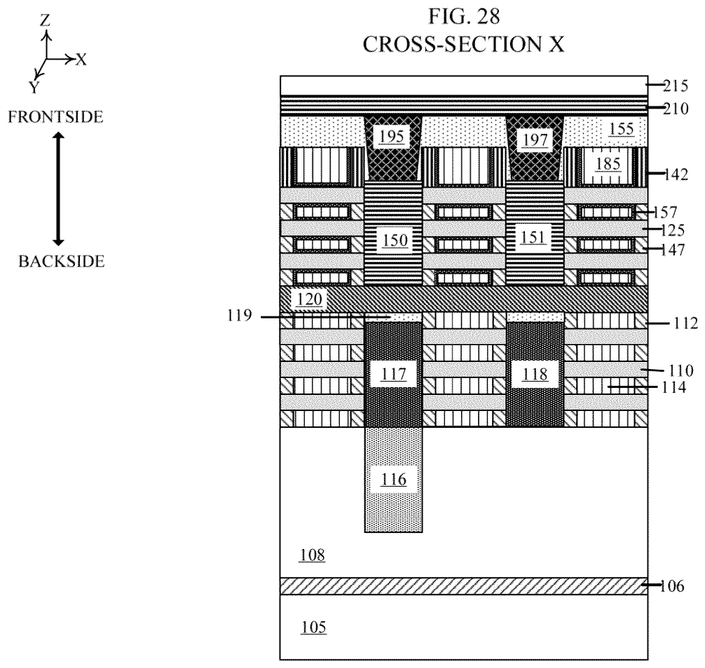

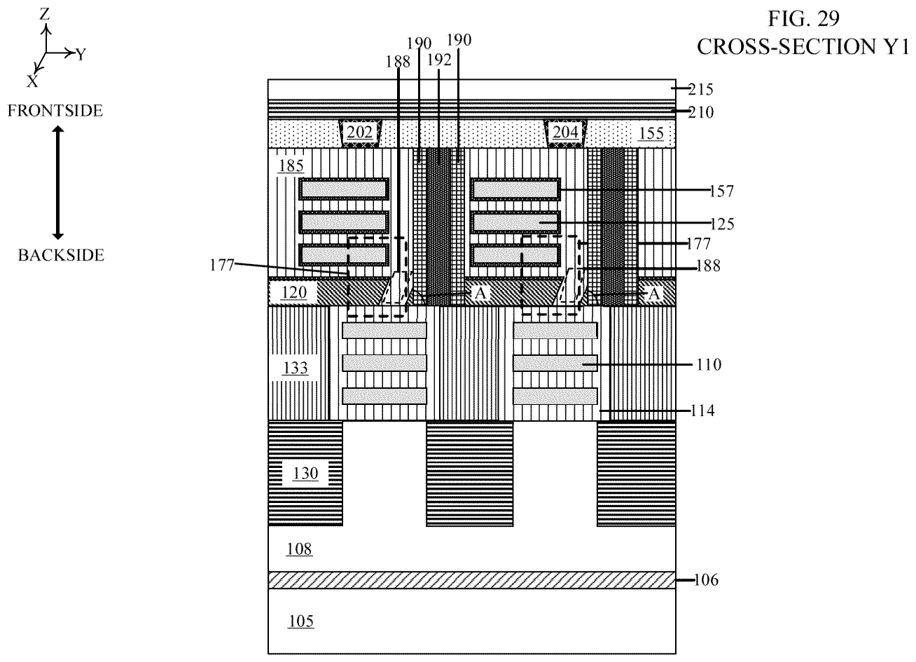

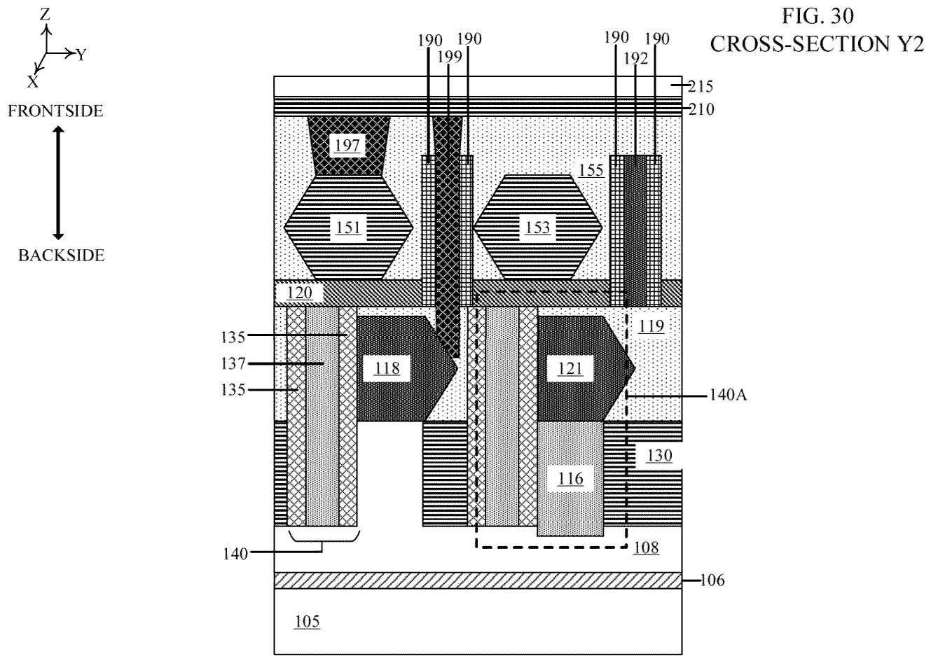

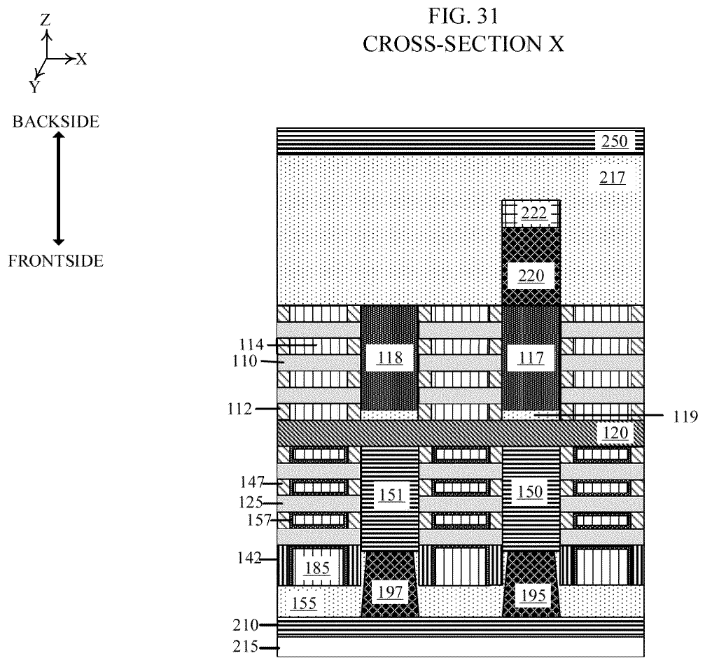

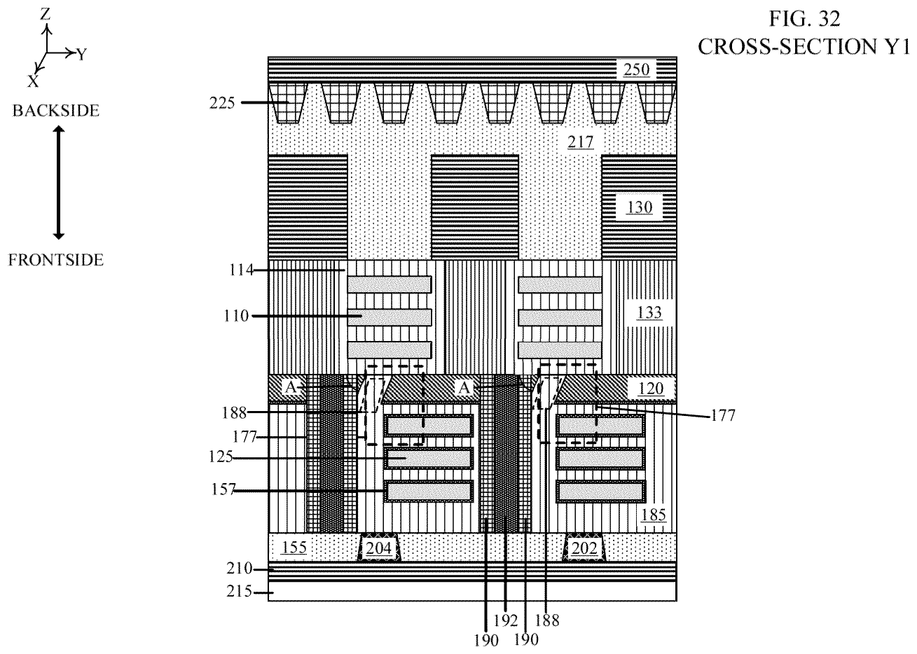

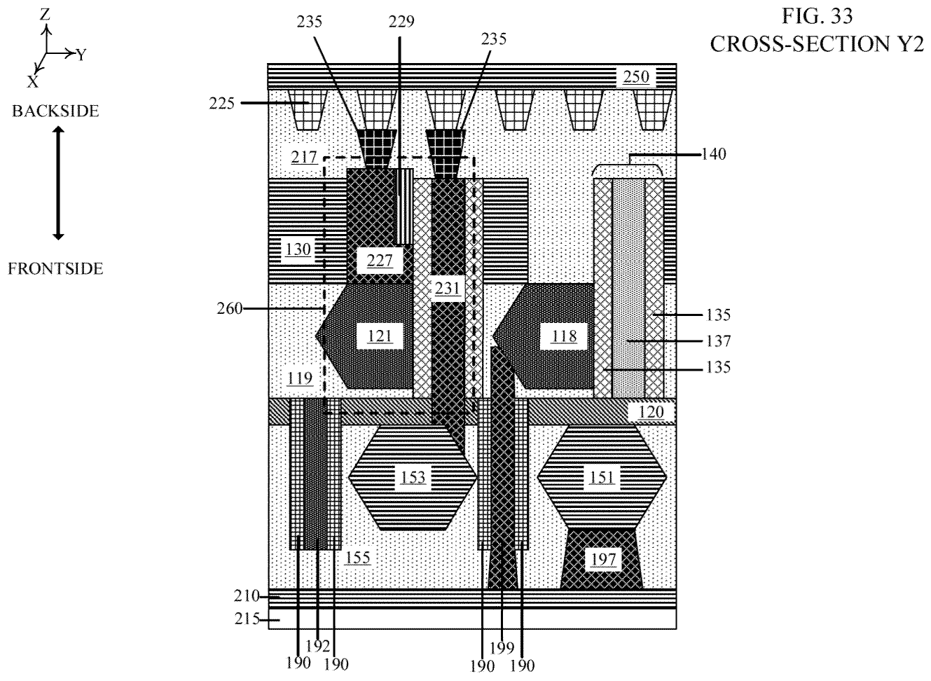

FIGS. 28, 29 and 30 illustrate the processing stage after additional frontside processing of the stacked FETs. The height of the upper frontside interlayer dielectric layer 155 is increased to extend the layer over the top of the upper gate 185. A plurality of trenches (not shown) are formed in the upper frontside interlayer dielectric layer 155, wherein each of the trenches (not shown) expose a different surface, for example, a top surface of the upper source/drain 150, 151, a top surface of the upper gate 185, and/or a portion of the core segment 192. The exposed portion of core segment 192 is removed to form a trench (not shown) within core segment 192. The trench (not shown) within core segment 192 extends downwards to expose a frontside surface of the bottom source/drain 118. These trenches (not shown) are filled with a conductive metal to form a plurality of contacts. FIG. 28 illustrates upper source/drain contacts 195, 197. FIG. 29 illustrates upper gate contacts 202, 204. Furthermore, FIG. 29 illustrates that the core segment 192 is not removed in the gate region. FIG. 30 illustrates the upper source/drain contact 197 and bottom core source/drain contact 199. The bottom core source/drain contact 199 is located where portion of the core segment 192 were removed. The bottom core source/drain contact 199 is located between the at least two vertical segments 190. The bottom core source/drain contact 199 extends through the bonding oxide layer 120 and the bottom frontside interlayer dielectric layer 119 to contact a surface of the bottom source/drain 118. A frontside interconnect 210 is formed on top the upper frontside interlayer dielectric layer 155 and on top of the formed frontside contacts (i.e., upper source/drain contacts 195, 197, upper gate contacts 202, 204, and bottom core source/drain contact 199). The frontside interconnect 210 can be, for example, a back-end-of-the-line (BEOL) layer, which can include a plurality of layers, a plurality of metal lines, a plurality of vias, etc. The frontside interconnect 210 is illustrated as a single layer for simplicity. A carrier wafer 215 is located on top of the frontside interconnect 210. The carrier wafer 215 allows for the stacked FETs device located on the wafer to be flipped over for backside processing. FIGS. 2-30 illustrated the frontside processing of the stacked FETs, while FIGS. 31-33 illustrate the stacked FETs after backside processing.

FIGS. 31, 29 and 30 illustrate the processing stage after backside processing of the stacked FETs. The stacked FETs device located on the wafer (i.e., the first substrate 105) are flipped over the expose the backside of the device for processing. The first substrate 105, the etch stop 106 and the second substrate 108 are removed. The removal of these layers exposes a surface of the bottom gate 114, the bottom inner spacer 112, bottom source/drains 117, 118, the shallow trench isolation layer 130, the bottom placeholder pillars 140, and the placeholders 116. A backside interlayer dielectric layer 217 is formed on the exposed surfaces. Trenches (not shown) are formed in the backside interlayer dielectric layer 217 to expose a surface of placeholder 116 and a portion of placeholder pillar 137. The exposed placeholders 116 are removed to expose a surface of the bottom source/drains 117, 121, a portion of placeholder pillar 137 are removed to form trenches (not shown). These trenches (not shown) are filled with a conductive metal to form backside source/drain contacts 220, 227, and a backside core source/drain contact 231. A portion of the backside source/drain contacts 220, 227 is removed to form a spacer trench (not shown), where the spacer trench (now shown) is located next to one of the vertical spacer segments 135. The spacer trench is filled with a dielectric material to form backside spacer 222, 229. The backside spacers 222, 229 can be located on top of and/or within the backside source/drain contacts 220, 227 as illustrated in FIG. 31, and 33. The backside spacer 222, 229 separates the backside source/drain contacts 220, 227 from adjacent elements, for example, the backside core source/drain contact 231 to prevent shorting. The backside core source/drain contact 231 extends through the bonding oxide layer 120 and the upper frontside interlayer dielectric layer 155 to make contact with a surface of the upper source/drain 153. The height of the backside interlayer dielectric layer 217 is increased to extend on top of the backside source/drain contacts 220, 227, and the backside core source/drain contact 231. A plurality of trenches (not shown) is formed in the backside interlayer dielectric layer 217. The plurality of trenches (not shown) is filled with a conductive metal to form a plurality of connection vias 235, and a plurality of metal lines 225. Each of the plurality of connection vias 235 connects a component (e.g., the backside source/drain contacts 220, 227, and the backside core source/drain contact 231) to one of the plurality of metal lines 225. The plurality of metal lines 225 can be, for example, power rails (i.e., VSS or VDD), signal lines, ground lines, clock lines, etc., or a combination thereof. A backside interconnect 250 is formed on top of the plurality of metal lines 225, and the backside interlayer dielectric layer 217. The backside interconnect 250 can be, for example, a backside-power-distribution-network (BSPDN), or an interconnect that includes a plurality of layers, a plurality of metal lines, a plurality of vias, or a combination thereof.

A microelectronic structure that includes a stacked FET. The stacked FET includes a frontside FET (upper channel layers 125, upper inner spacer 147, upper gate spacer 142, upper gate 185, upper source/drains 150, 151, 153) and a backside FET (bottom channel layers 110, bottom inner spacer 112, bottom gate 114, and bottom source/drains 117, 118, 121). The frontside FET includes a frontside gate (upper gate 185) and the backside FET includes a backside gate (bottom gate 114). A bonding oxide layer 120 separates the frontside FET and the backside FET. An angled shared gate connection 188 located in the bonding oxide layer 120 that connects the frontside gate 185 to the backside gate 114.

A frontside gate cut (or upper gate cut) located adjacent to the frontside gate 185 and the frontside gate cut contacts the backside gate 114.

The angled shared gate connection 188 is angled away from the frontside gate cut. The angled shared gate connection 188 forms an acute angle (angle A) when measured from the top of the backside gate 114 to a surface of the angled shared gate connection 188 that is closer to the frontside gate cut. The acute angle (angle A) of the angled shared gate connection 188 in a range of about 35 to 75 degrees, more preferably in a range of about 45 to 65 degrees.

The frontside gate cute includes at least two vertical segments 190 and a core segment 190. One of the at least vertical segments 190 of the frontside gate contacts a portion of angled shared gate connection 188.

A microelectronic structure that includes a stacked FET. The stacked FET includes a frontside FET (upper channel layers 125, upper inner spacer 147, upper gate spacer 142, upper gate 185, upper source/drains 150, 151, 153) and a backside FET (bottom channel layers 110, bottom inner spacer 112, bottom gate 114, and bottom source/drains 117, 118, 121). The frontside FET includes a frontside gate (upper gate 185) and the backside FET includes a backside gate (bottom gate 114). A bonding oxide layer 120 separates the frontside FET and the backside FET. An angled shared gate connection 188 located in the bonding oxide layer 120 that connects the frontside gate 185 to the backside gate 114. A frontside gate cut (or upper gate cut) located adjacent to the frontside gate 185 and the frontside gate cut contacts the backside gate 114. The frontside gate cut is located in a gate region and the source/drain region of the frontside FET. A bottom core source/drain contact 199 extends through the frontside gate cut in the source/drain region to contact the backside source/drain 118.

The angled shared gate connection 188 is angled away from the frontside gate cut. The angled shared gate connection 188 forms an acute angle (angle A) when measured from the top of the backside gate 114 to a surface of the angled shared gate connection 188 that is closer to the frontside gate cut. The acute angle (angle A) of the angled shared gate connection 188 in a range of about 35 to 75 degrees, more preferably in a range of about 45 to 65 degrees.

The frontside gate cute includes at least two vertical segments 190 and a core segment 190. One of the at least vertical segments 190 of the frontside gate contacts a portion of angled shared gate connection 188.

A microelectronic structure that includes a stacked FET. The stacked FET includes a frontside FET (upper channel layers 125, upper inner spacer 147, upper gate spacer 142, upper gate 185, upper source/drains 150, 151, 153) and a backside FET (bottom channel layers 110, bottom inner spacer 112, bottom gate 114, and bottom source/drains 117, 118, 121). The frontside FET includes a frontside gate (upper gate 185) and a plurality of frontside channel layers 125. The backside FET includes a backside gate (bottom gate 114). A bonding oxide layer 120 separates the frontside FET and the backside FET. An angled shared gate connection 188 located in the bonding oxide layer 120 that connects the frontside gate 185 to the backside gate 114. The angled shared gate connection 188 and the frontside channel layers 125 vertically overlap.

A frontside gate cut (or upper gate cut) located adjacent to the frontside gate 185 and the frontside gate cut contacts the backside gate 114.

The angled shared gate connection 188 is angled away from the frontside gate cut. The angled shared gate connection 188 forms an acute angle (angle A) when measured from the top of the backside gate 114 to a surface of the angled shared gate connection 188 that is closer to the frontside gate cut. The acute angle (angle A) of the angled shared gate connection 188 in a range of about 35 to 75 degrees, more preferably in a range of about 45 to 65 degrees.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a stacked FET that includes a frontside FET and a backside FET, wherein the frontside FET includes a frontside gate and the backside FET includes a backside gate;
a bonding oxide layer separates the frontside FET and the backside FET; and
an angled shared gate connection located in the bonding oxide layer that connects the frontside gate to the backside gate.

2. The microelectronic structure of claim 1, further comprising:
a frontside gate cut located adjacent to the frontside gate, wherein the frontside gate cut contacts the backside gate.

3. The microelectronic structure of claim 2, wherein the angled shared gate connection is angled away from the frontside gate cut.

4. The microelectronic structure of claim 3, where the angled shared gate connection forms an acute angle when measured from the top of the backside gate to a surface of the angled shared gate connection that is closer to the frontside gate cut.

5. The microelectronic structure of claim 4, wherein the acute angle of the angled shared gate connection in a range of about 35 to 75 degrees.

6. The microelectronic structure of claim 5, wherein the acute angle of the angled shared gate connection is preferably in a range of about 45 to 65 degrees.

7. The microelectronic structure of claim 2, wherein the frontside gate cute includes at least two vertical segments and a core segment.

8. The microelectronic structure of claim 7, wherein one of the at least vertical segments of the frontside gate contacts a portion of angled shared gate connection.

9. A microelectronic structure comprising:
a stacked FET that includes a frontside FET and a backside FET, wherein the frontside FET includes a frontside gate and the backside FET includes a backside gate, wherein the backside FET includes a backside source/drain;
a bonding oxide layer separates the frontside FET and the backside FET;
an angled shared gate connection located in the bonding oxide layer that connects the frontside gate to the backside gate;
a frontside gate cut located adjacent to the frontside gate, wherein the frontside gate cut contacts the backside gate, wherein the frontside gate cut is located in a gate region and the source/drain region of the frontside FET; and
a bottom core source/drain contact extends through the frontside gate cut in the source/drain region to contact the backside source/drain.

10. The microelectronic structure of claim 9, wherein the angled shared gate connection is angled away from the frontside gate cut.

11. The microelectronic structure of claim 10, where the angled shared gate connection forms an acute angle when measured from the top of the backside gate to a surface of the angled shared gate connection that is closer to the frontside gate cut.

12. The microelectronic structure of claim 11, wherein the acute angle of the angled shared gate connection in a range of about 35 to 75 degrees.

13. The microelectronic structure of claim 12, wherein the acute angle of the angled shared gate connection is preferably in a range of about 45 to 65 degrees.

14. The microelectronic structure of claim 13, wherein the frontside gate cute includes at least two vertical segments and a core segment.

15. The microelectronic structure of claim 14, wherein one of the at least vertical segments of the frontside gate contacts a portion of angled shared gate connection.

16. A microelectronic structure comprising:
a stacked FET that includes a frontside FET and a backside FET, wherein the frontside FET includes a frontside gate and a plurality of frontside channel layers, wherein the backside FET includes a backside gate;
a bonding oxide layer separates the frontside FET and the backside FET; and
an angled shared gate connection located in the bonding oxide layer that connects the frontside gate to the backside gate, wherein the angled shared gate connection and the frontside channel layers vertically overlap.

17. The microelectronic structure of claim 16, further comprising:
a frontside gate cut located adjacent to the frontside gate, wherein the frontside gate cut contacts the backside gate.

18. The microelectronic structure of claim 17, wherein the angled shared gate connection is angled away from the frontside gate cut.

19. The microelectronic structure of claim 16, where the angled shared gate connection forms an acute angle when measured from the top of the backside gate to a surface of the angled shared gate connection that is closer to the frontside gate cut.

20. The microelectronic structure of claim 19, wherein the acute angle of the angled shared gate connection in a range of about 35 to 75 degrees, preferably in a range of about 45 to 65 degrees.
